(19) United States
(12) Patent Application Publication
(10) Pub. No.: US 2009/0191029 A1
(43) Pub. Date: Jul. 30, 2009

(54) SYSTEM FOR HANDLING SEMICONDUCTOR DIES

(76) Inventors: Taeg Ki Lim, Icheon (KR); Jason Lee, Seoul (KR); Gab Yong Min, Ichon-Si (KR); Jung Ho Kim, Yuju-gun (KR)

Correspondence Address: LAW OFFICES OF MIKIO ISHIMARU, 333 W. EL CAMINO REAL, SUITE 330, SUNNYVALE, CA, 94087, US

(21) Appl. No.: 12/022,308

(22) Filed: Jan. 30, 2008

(51) Int. Cl. H01L 21/677

(52) U.S. Cl. 414/217

(57) ABSTRACT

The present invention provides a system for handling semiconductor dies, comprising providing a semiconductor die adhered to a tacky tape, cooling the semiconductor die and the tacky tape to reduce the adhesion between the semiconductor die and the tacky tape, separating the semiconductor die from the tacky tape, and moving the semiconductor die.

### TECHNICAL FIELD

The present invention relates generally to semiconductor packaging technology, and more particularly to a system for extracting dies from a tacky tape or membrane for mounting into a semiconductor package.

### BACKGROUND ART

Semiconductor dies (or “chips”) containing integrated circuits or integrated optoelectronic systems are manufactured within semiconductor substrates called wafers. Each wafer contains very large numbers of dies. Once wafer-level manufacturing is complete, the wafers are placed on sheets of adhesive tape, and sawed to form individual semiconductor dies. The dies are then handled individually for transport, further testing, or attachment to a chip package.

As new generations of electrical consumer products are developed there is a growing need to improve the functionality, performance, reliability, and manufacturing robustness of IC packages. Additionally, miniaturization of handheld devices such as cell phones and smart cards impose restrictions on the overall thickness of the package. The reduced package thickness requirement has led to significant thinning of the semiconductor dies, resulting in die thicknesses of less than 50 micrometers. Each die handling step represents a risk of damage, particularly if the die is thinned for low-profile packaging.

Equipment used for handling of semiconductor dies generally separate the semiconductor die from an adhesive sheet (also known as a “tacky membrane” or “tacky tape”) and move it to a different tacky tape or directly onto a package. Separation of the semiconductor die from the tacky tape is accomplished using an ejector head that pushes the semiconductor die from underneath the tacky tape. Concurrently a handling arm picks up the semiconductor die using suction.

It has been found that as the die thickness is reduced below 100 micrometers, the approach used for de-attaching the die from the tape induces manufacturing yield loss from reliability problems and cracking of the die. This yield loss has a significant impact on the cost of the packaging process since the dies are generally pre-sorted at the wafer level and are not tested again until after they are packaged. The failure of a packaged chip adds the cost of the package, package assembly, and package-level testing to the loss of the chip.

Thus, a need still remains for a system for handling semiconductor dies that is able to separate the thin dies from a tacky tape or membrane without inducing mechanical damage of the die or yield loss due to reliability problems induced by the die handling steps. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a system for handling semiconductor dies, comprising providing a semiconductor die adhered to a tacky tape, cooling the semiconductor die and the tacky tape to reduce the adhesion between the semiconductor die and the tacky tape, separating the semiconductor die from the tacky tape, and moving the semiconductor die.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a schematic diagram of a system for handling semiconductor dies in an embodiment of the present invention;

FIG. 2 is a schematic diagram of the system for handling semiconductor dies during a die detection step of the semiconductor die handling process;

FIG. 3 is a schematic diagram of the system for handling semiconductor dies during a die cooling step of the chip handling process;

FIG. 4 is a schematic diagram of the system for handling semiconductor dies during a die separation step of the chip handling process;

FIG. 5 is a schematic diagram of the system for handling semiconductor dies during a die movement step of the chip handling process;

FIG. 6 is a signaling diagram of a control system in the system for handling semiconductor dies of the present invention; and

FIG. 7 is a flow chart of the system for handling semiconductor dies in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown exaggerated in the drawing FIGs. In addition, where multiple embodiments are disclosed and described having some features in common, for clarity and ease of illustration, description, and comprehension thereof, like features one to another will ordinarily be described with like reference numerals.

For expository purposes, the term “horizontal” as used herein is defined as a plane parallel to the plane or surface of the semiconductor die, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means that there is direct contact among elements.

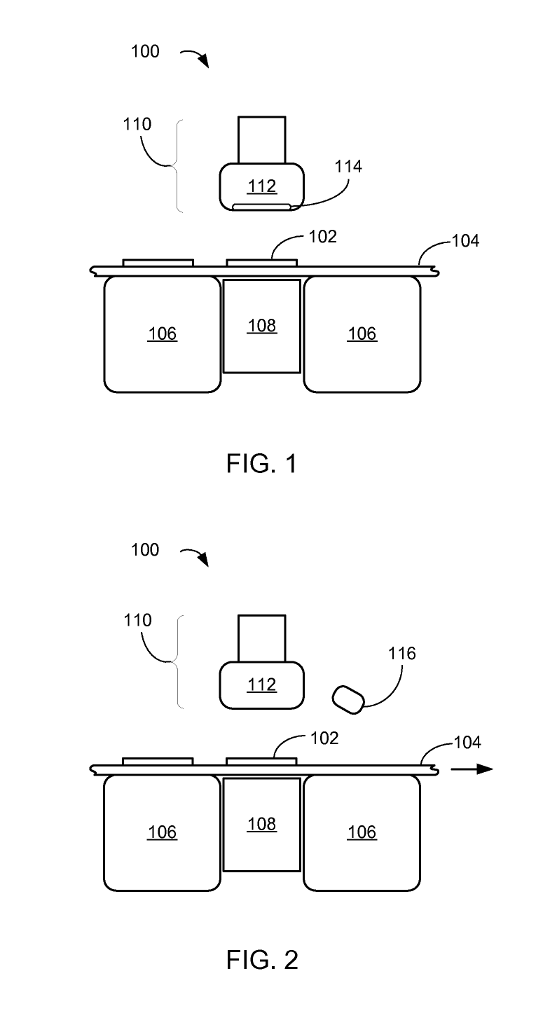

Referring now to FIG. 1, therein is shown a schematic diagram of a system for handling semiconductor dies 100 in an embodiment of the present invention. A semiconductor die 102 adhered to a tacky tape 104 is placed on top of a handling stage 106 containing a bottom cooling stage 108. The bottom cooling stage 108 may be moved vertically to provide better contact to the tacky tape 104 or to push the tacky tape 104 upward. A handling arm 110 placed on top of the semiconductor die 102 incorporates a top cooling stage 112 and a suction mechanism 114 that is used to form a seal between the top cooling stage 112 and the semiconductor die 102.

The purpose of the handling arm 110 is to separate the semiconductor die 102 from the tacky tape 104 and then move the semiconductor die 102 to a different location. It has been unexpectedly discovered that by cooling the tacky tape 104 below zero degrees Celsius it is possible to separate the semiconductor die 102 from the tacky tape 104 without breakage or a reliability impact on the semiconductor die 102, even when the semiconductor die 102 is thinner than 50 microns. This risk reduction in handling the semiconductor die 102 significantly reduces costs from yield loss. It is hypothesized that cooling of the tacky tape 102 below zero degrees Celsius reduces the adhesive strength of the tacky tape 104 and increases the stiffness of the tacky tape 104, greatly facilitating the separation of the semiconductor die 102 from the tacky tape 104.

Referring now to FIG. 2, therein is shown a schematic diagram of the system for handling semiconductor dies 100 during a die detection step of the chip handling process. In this step, the tacky tape 104 is moved over the handling stage 106 to center the semiconductor die 102 over the bottom cooling stage 108. In one embodiment of the present invention, a detector cluster 116, provides measurements of system function, including the position of the semiconductor die 102 in reference to the bottom cooling stage 108, the temperature of the semiconductor die 102, the position and temperature of the bottom cooling stage 108, and the position and temperature of the top cooling stage 112. During the detection step, the handling arm 110 remains in its “home position.”

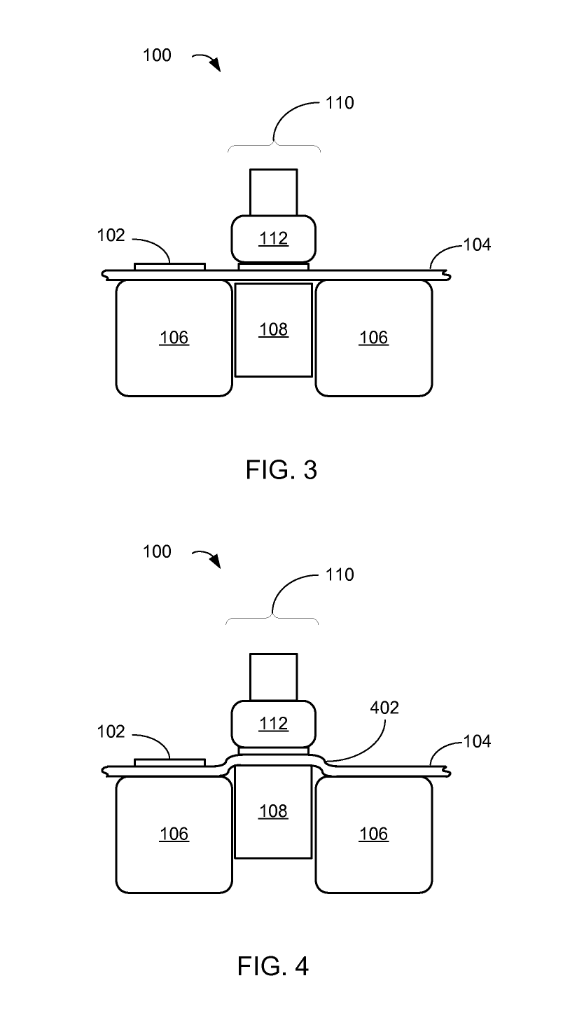

Referring now to FIG. 3, therein is shown a schematic diagram of the system for handling semiconductor dies 100 during a die cooling step of the chip handling process. In this step the semiconductor die 102 and the tacky tape 104 are cooled below 0 degrees Celsius in order to reduce the adhesion strength of the tacky tape 104.

In one embodiment of the invention, the bottom cooling stage 108 is placed in contact with the tacky tape 104 and the handling arm 110 is moved such that the top cooling stage 112 is in contact with the semiconductor die 102. The temperature of the semiconductor die 102 and of the tacky tape 104 is reduced rapidly to maximize throughput of the handling process. Pre-cooling the bottom cooling stage 108 and the top cooling stage 112 to the desired set point provides a rapid temperature shock when the semiconductor die 102 is moved over the bottom cooling stage 108. In an alternate embodiment of the invention only the bottom cooling stage 108 provides the cooling.

Referring now to FIG. 4, therein is shown a schematic diagram of the system for handling semiconductor dies 100 during a die separation step of the chip handling process. In this step the semiconductor die 102 and the tacky tape 104 directly underneath the semiconductor die 102 are already cooled below 0 degrees Celsius. As a result of the low temperature the adhesion strength of the tacky tape 104 is reduced significantly. Suction is applied under the top cooling stage 112 providing traction between the top cooling stage 112 and the semiconductor die 102. Concurrently, the bottom cooling stage 108 is moved upward to induce a bend 402 of the tacky tape 104. The handling arm 110 is also moved upward to separate the semiconductor die 102 from the tacky tape 104.

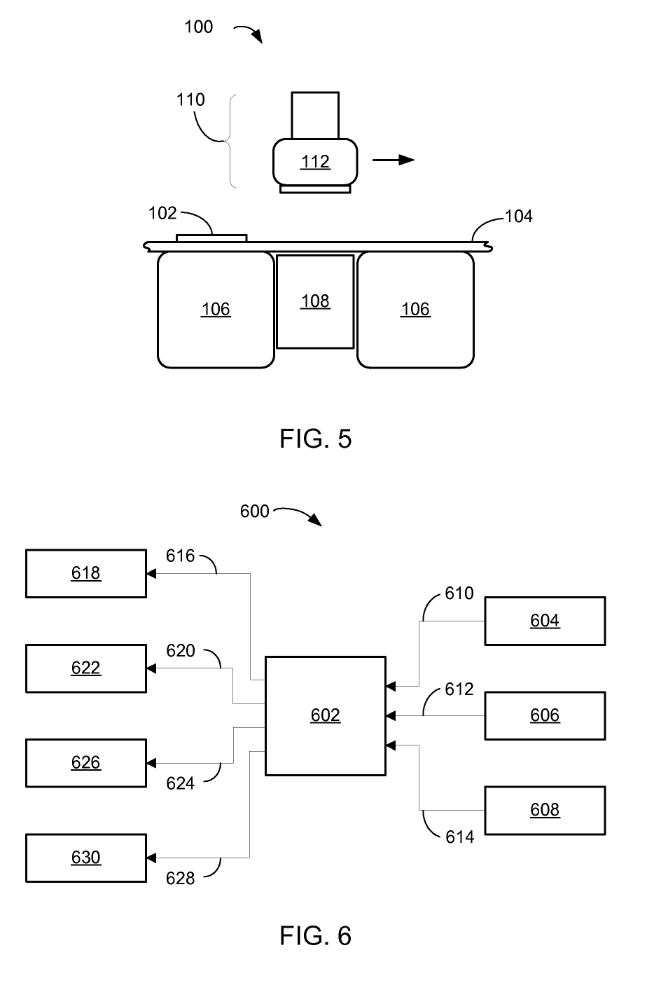

Referring now to FIG. 5, therein is shown a schematic diagram of the system for handling semiconductor dies 100 during a die movement step of the chip handling process. In this step, the semiconductor die 102 has been separated from the tacky tape 104. The bottom cooling stage 108 is moved back down to the initial home position. The handling arm 110 moves the semiconductor die 102 away from the tacky tape 104 and to a new location.

Referring now to FIG. 6, therein is shown a signaling diagram of a control system 600 in the system for handling semiconductor dies 100 of the present invention. The control system 600 includes a microprocessor 602, a die-position sensor 604, a die-temperature sensor 606, and a pull-force sensor 608. These sensors are part of the detector cluster 116 shown in FIG. 2. The die-position sensor 604 produces a position signal 610 that indicates the position of the semiconductor die 102 in FIG. 1 in reference to the bottom cooling stage 108 in FIG. 1. The die-temperature sensor 606 generates a temperature signal 612 that corresponds to the temperature of the semiconductor die 102 in FIG. 1. The pull-force sensor 608, produces a pull-force signal 614 that is indicative of the pull-force applied by the handling arm 110 (FIG. 1) as the semiconductor die 102 (FIG. 1) is separated from the tacky tape 104 (FIG. 1).

In the operation of the control system 600, the microprocessor generates a temperature control signal 616 for a temperature control mechanism 618 that sets the temperature of the bottom cooling stage 108 and the top cooling stage 112 shown in FIG. 1, a tape-motion control signal 620 for a tape-motion control mechanism 622 that controls the position of the tacky tape 104 in FIG. 1, a handling arm motion control signal 624 for a handling arm motion mechanism 626 that actuates the handling arm 110 in FIG. 1, and a bottom stage motion control signal 628 for a bottom stage motion mechanism 630 that actuates the movement of the bottom cooling stage in FIG. 1. Additional sensors and mechanisms may be incorporated to implement the die separation and handling process.

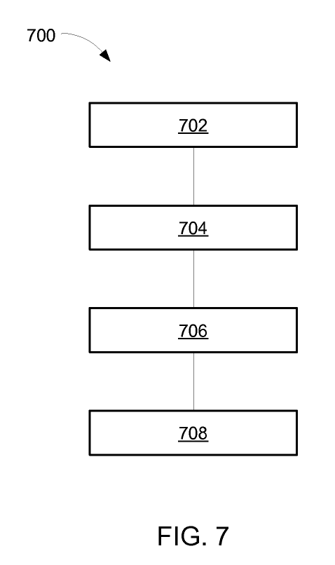

Referring now to FIG. 7, therein is shown a flow chart of a system for handling semiconductor dies 700 in an embodiment of the present invention. The system for handling semiconductor dies 700 includes providing a semiconductor die mounted on a tacky tape in a block 702; cooling the semiconductor die and the tacky tape to reduce the adhesion strength between the semiconductor die and the tacky tape in a block 704; separating the semiconductor die and the tacky tape in a block 706; and moving the freed semiconductor die in a block 708.

It has been discovered that the present invention thus has numerous aspects.

A principal aspect that has been unexpectedly discovered is that the present invention is capable of separating the semiconductor die from the tacky tape without breaking the semiconductor die or impacting its reliability.

Another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the system for handling semiconductor dies of the present invention furnishes important and heretofore unknown and unavailable solutions, capabilities, and functional aspects for reliably handling semiconductor dies adhered to a tacky tape. The resulting processes and configurations are straightforward, cost-effective, uncomplicated, highly versatile and effective, can be surprisingly and unobviously implemented by adapting known technologies, and are thus readily suited for efficiently and economically manufacturing semiconductor dies and packages for semiconductor dies fully compatible with conventional manufacturing processes and technologies.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A system for handling semiconductor dies, comprising:
providing a semiconductor die adhered to a tacky tape;
cooling the semiconductor die and the tacky tape to reduce the adhesion between the semiconductor die and the tacky tape;
separating the semiconductor die from the tacky tape; and
moving the semiconductor die.

2. The system as claimed in claim 1 wherein cooling of the semiconductor die and the tacky tape reduces the temperature of the tacky tape below zero degrees Celsius.

3. The system as claimed in claim 1 wherein cooling of the semiconductor die and the tacky tape is performed using a bottom cooling stage placed underneath the tacky tape.

4. The system as claimed in claim 1 wherein the cooling of the semiconductor die and the tacky tape is performed using a top cooling stage placed on top of the semiconductor die.

5. The system as claimed in claim 1 wherein separating the semiconductor die from the tacky tape is performed using a handling arm that pulls the semiconductor die from the tacky tape.

6. A system for handling semiconductor dies, comprising:
providing a semiconductor die adhered to a tacky tape;
aligning the semiconductor die to a bottom cooling stage;
cooling the semiconductor die and the tacky tape to reduce the adhesion between the semiconductor die and the tacky tape;
separating the semiconductor die from the tacky tape by pulling the semiconductor die using a handling arm; and
moving the semiconductor die using the handling arm.

7. The system as claimed in claim 6 wherein cooling of the semiconductor die is applied to induce a sudden change in the temperature of the semiconductor die and the tacky tape in the proximity of the semiconductor die.

8. The system as claimed in claim 6 wherein separating the semiconductor die from the tacky tape is facilitated by pressing the bottom cooling stage against the tacky tape, thereby inducing a bend that initiates delamination of the semiconductor die from the tacky tape.

9. The system as claimed in claim 6 wherein separating the semiconductor die from the tacky tape is performed while controlling the temperature of the semiconductor die.

10. The system as claimed in claim 6 wherein the separating the semiconductor die from the tacky tape is performed while controlling the pulling force exerted by the handling arm.

11. A system for handling semiconductor dies, comprising:
a handling stage for supporting a semiconductor die mounted on a tacky tape;
a bottom cooling stage for cooling the semiconductor die and the tacky tape underneath the semiconductor die; and
a handling arm for separating the semiconductor die from the tacky tape.

12. The system as claimed in claim 11 further comprising a top cooling stage for cooling the semiconductor die and the tacky tape underneath the semiconductor die.

13. The system as claimed in claim 11 further comprising a detector cluster incorporating a die-temperature sensor for monitoring the temperature of the semiconductor die.

14. The system as claimed in claim 11 further comprising a detector cluster incorporating a die-position sensor for monitoring the position of the semiconductor die relative to the bottom cooling stage.

15. The system as claimed in claim 11 wherein the handling arm incorporates a pull-force sensor for monitoring the pull force applied on the semiconductor die.

16. The system as claimed in claim 11 further comprising a detector cluster and a control system incorporating a microprocessor for processing signals from the detection cluster.

17. The system as claimed in claim 16 further comprising a temperature control mechanism for adjusting the temperature of the bottom cooling stage or the temperature of the top cooling stage.

18. The system as claimed in claim 16 further comprising a tape-motion control mechanism for adjusting the position of the semiconductor die using a tape motion control signal from the microprocessor.

19. The system as claimed in claim 16 further comprising a handling arm motion mechanism for actuating the handling arm using a handling arm motion control signal from the microprocessor.

20. The system as claimed in claim 16 further comprising a bottom stage motion mechanism for actuating the movement of the bottom cooling stage using a bottom stage control signal from the microprocessor.
